(19) United States
(12) Patent Application Publication
(10) Pub. No.: US 2007/0159264 A1
(43) Pub. Date: Jul. 12, 2007

(54) Phase-locked loop with adaptive bandwidth

(75) Inventors: Woo-Young Jung, Yongin-si (KR); Young-Min Kim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/646,101

(22) Filed: Dec. 27, 2006

(30) Foreign Application Priority Data
Jan. 10, 2006 (KR) 10-2006-0002714

(51) Int. Cl. H03L 7/00

(52) U.S. Cl. 331/16

(57) ABSTRACT

In case that a frequency bandwidth of an output signal of a phase-locked loop (PLL) depends upon a current provided from a charge pump, a control current provided from a voltage-current (VI) converter, a resistance of a loop filter, a conversion constant of the VI converter and a reference frequency applied to a phase-frequency detector (PFD), in the PLL, a variation of the current provided from the charge pump due to effects of process, voltage and temperature (PVT) cancels with a variation of the control current provided from the VI converter due to effects of PVT, and a variation of the resistance of the loop filter due to effects of PVT cancels with a variation of the conversion constant of the VI converter due to effects of PVT.

### CROSS-REFERENCE TO RELATED APPLICATIONS

This application claims priority under 35 USC §119 to Korean Patent Application No. 10-2006-0002714, filed on Jan. 10, 2006 in the Korean Intellectual Property Office (KIPO), the contents of which are herein incorporated by reference in its entirety.

### BACKGROUND OF THE INVENTION

1. Field of the Invention

The present invention relates to a phase-locked loop, and more particularly to a phase-locked loop of which bandwidth is insensitive to process, voltage and temperature variations.

2. Description of the Related Art

A phase-locked loop (PLL) capable of outputting a clock signal having a variable frequency is used in various ways.

Generally, a PLL includes a divider in a feedback path wherein a division ratio of the divider has a value of M. The PLL can generate a clock signal having a high frequency by receiving a reference signal having a low frequency, and generate a clock signal having a desired frequency by controlling the division ratio.

However, a frequency band and/or jitter characteristics in the PLL can vary according to the division ratio, and be sensitive to process, voltage and temperature (PVT) variations.

The PLL is widely used in portable devices, and thus a need for reducing size and power consumption of the PLL has become more important. Thus, PVT variations that affect a frequency band and/or jitter characteristics should be considered weighty.

FIG. 1 is a block diagram illustrating a PLL including a conventional voltage-controlled oscillator (VCO). Referring to FIG. 1, a PLL 10 includes a phase-frequency detector (PFD) 11, a charge pump 12, a loop filter 13, a VCO 14 and a main divider 15.

The PLL 10 receives a reference signal φIN having a reference frequency FREF (or F_{REF}) to generate an output signal φOUT of which a frequency is M times the reference frequency F_{REF} of the reference signal φIN. The PFD 11 detects a phase difference between the reference signal φIN and the output signal φOUT. If the phase difference is greater than a predetermined phase difference Δφ, the PFD 11 generates an up signal or a down signal to provide the up signal or the down signal to the charge pump 12. The charge pump 12 provides a predetermined current ICP/2π to the loop filter 13 according to the up signal or the down signal. The loop filter 13 receives the predetermined current to generate a voltage to be supplied to the VCO 14 and maintains the voltage constant. The VCO 14 receives the voltage to generate the output signal φOUT, of which the frequency is proportional to the received voltage, with a proportional constant K_{VCO}. The main divider 15 receives the output signal φOUT to generate a divided output signal, of which a frequency is 1/M times that of the output signal φOUT. The divided output signal is applied to the PFD 11. As described above, the PLL 10 can generate the output signal φOUT, of which the frequency is maintained substantially constant.

A transfer function of the PLL 10 is obtained as shown below.

$$\begin{matrix}{G}_{1} ( s ) = \frac{{φ}_{OUT}}{{φ}_{IN}} = \frac{\frac{{I}_{CP}}{2 π} \cdot H ( s ) \cdot \frac{{K}_{VCO}}{s}}{1 + \frac{{I}_{CP}}{2 π} \cdot H ( s ) \cdot \frac{{K}_{VCO}}{s}} \\ = \frac{\frac{{I}_{CP} \cdot {K}_{VCO}}{2 π \cdot {C}_{LP}} \cdot ( 1 + {sR}_{LP} \cdot {C}_{LP} )}{{s}^{2} + \frac{{I}_{CP} \cdot {K}_{VCO} \cdot {R}_{LP} )}{2 π \cdot M} \cdot s + \frac{{I}_{CP} \cdot {K}_{VCO}}{2 π \cdot M \cdot {C}_{LP}}}\end{matrix} \\ ( where H ( s ) \approx \frac{1 + {sR}_{LP} \cdot {C}_{LP}}{{sC}_{LP}} ) \qquad [ Expression 1 ]$$

wherein I_{CP} indicates a current provided from the charge pump 12, H(s) indicates an approximate function of a transfer function of the loop filter 13, K_{VCO} indicates a proportional constant of the VCO 14, C_{LP} indicates a capacitance of the loop filter 13, and R_{LP} indicates a resistance of the loop filter 13.

A bandwidth Δω of the PLL 10 is obtained using Expression 2 below, which is taken from a denominator of the transfer function G₁(s) in Expression 1.

$$Δ w = \frac{{I}_{CP} \cdot {K}_{VCO} \cdot {R}_{LP}}{2 π \cdot M} \qquad [ Expression 2 ]$$

Referring to Expression 2, the bandwidth Δω depends upon the current I_{CP} provided from the charge pump 12, the resistance R_{LP} of the loop filter 13, the proportional constant K_{VCO} of the VCO 14 and the division ratio M of the main divider 15. Thus, the PLL 10 is sensitive to PVT variations.

In addition, a loop filter in a PLL includes a large capacitor and a resistor. Generally, when a circuit is formed in a semiconductor chip, a capacitor occupies a large area in the semiconductor chip. In case that the resistance in the loop filter is increased so as to reduce size of the capacitor and maintain characteristics of the loop filter, a bandwidth of the PLL is increased as shown in Expression 2. In case that a current provided from the charge pump is reduced so as to reduce the size of the capacitor in the loop filter and maintain the bandwidth, characteristics of the PLL actually become difficult to preserve. In other words, reducing the size of the capacitor is not easy, and as a result, reducing the size of the PLL is difficult.

### SUMMARY OF THE INVENTION

In accordance with aspects of the present invention, provided is a phase-locked loop (PLL), of which a frequency bandwidth is insensitive to a division ratio and process, voltage, and temperature (PVT) variations.

In accordance with one aspect of the invention, provided is a PLL that includes a phase-frequency detector (PFD), a charge pump, a loop filter, a voltage-current (VI) converter, a current-controlled oscillator (CCO) and a divider, and generates an output signal having a predetermined output frequency. The VI converter includes a first transistor, a second transistor, a feedback resistor and a third transistor. The first transistor has a gate receiving a control voltage provided from the loop filter, the second transistor has a gate receiving a drain voltage of the first transistor and a source receiving a power supply voltage, the feedback resistor converts a drain voltage of the second transistor into a control current according to a conversion constant, and the third transistor has a gate receiving the drain voltage of the second transistor.

In accordance with another aspect of the invention, provided is a PLL that includes a PFD, a charge pump, a loop filter, a VI converter, a CCO and a divider, and generates an output signal having a predetermined output frequency. The VI converter includes a unit-gain amplifier and a feedback resistor. The unit-gain amplifier is configured to receive a control voltage provided from the loop filter, and the feedback resistor is configured to receive an output voltage of the unit-gain amplifier to generate a control current.

In accordance with another aspect of the invention, provided is a PLL that includes a PFD, a charge pump, a loop filter, a VI converter, a CCO and a divider, wherein the PLL is configured to generate an output signal having a predetermined output frequency. A frequency bandwidth of the output signal of the PLL depends upon a current provided from the charge pump, a control current provided from the VI converter, a resistance of the loop filter, a conversion constant of the VI converter and a reference frequency applied to the PFD, and the VI converter is configured to cancel a variation of the current provided from the charge pump due to effects of PVT with a variation of the control current provided from the VI converter due to effects of PVT, and is configured to cancel a variation of the resistance of the loop filter due to effects of PVT with a variation of the conversion constant of the VI converter due to effects of PVT.

The VI converter can include a first transistor, a second transistor, a feedback resistor and a third transistor. The first transistor can have a gate configured to receive a control voltage provided from the loop filter, the second transistor can have a gate configured to receive a drain voltage of the first transistor and a source receiving a power supply voltage, the feedback resistor can be configured to convert a drain voltage of the second transistor into the control current according to the conversion constant, and the third transistor can have a gate configured to receive the drain voltage of the second transistor.

The VI converter can include a unit-gain amplifier and a feedback resistor. The unit-gain amplifier can be configured to receive a control voltage provided with the loop filter, and the feedback resistor can be configured to receive an output voltage of the unit-gain amplifier to generate the control current.

The VI converter can be configured to convert a control voltage provided from the loop filter into the control current according to the conversion constant, and the CCO can be configured to receive the control current to generate the output signal with a linear approximation.

The CCO can comprise an inverter ring oscillator including N inverters serially coupled with each other, wherein N indicates an odd natural number, and an output of an Nth inverter is fed back into a first inverter.

The CCO can be comprise a differential inverter ring oscillator including M differential inverters serially coupled with each other, wherein M indicates a natural number, and an output of an Mth differential inverter is cross-coupled to a first differential inverter so as to be fed back into the first inverter.

In accordance with various aspects of the invention, the PLL can maintain characteristics of the original circuit and reduce a size of a capacitor of a loop filter, thereby reducing a size of the PLL as a whole.

### BRIEF DESCRIPTION OF THE DRAWINGS

The drawing figures depict preferred embodiments by way of example, not by way of limitations. In the figures, like reference numerals refer to the same or similar elements.

FIG. 1 is a block diagram illustrating a phase-locked loop (PLL) including a prior art voltage-controlled oscillator (VCO).

FIG. 2 is a block diagram illustrating an example embodiment of a PLL, according to aspects of the present invention, including a current-controlled oscillator (CCO).

FIG. 3 is a circuit diagram illustrating an example embodiment of a voltage-current (VI) converter and a CCO according to aspects of the present invention.

FIG. 4 is a graph illustrating a characteristic curve of a VI conversion in a VI converter included in an example embodiment of a PLL according to aspects of the present invention, and an approximate plot thereof.

FIG. 5 is a circuit diagram illustrating another embodiment of a VI converter in FIG. 2 according to another aspect of the present invention.

### DESCRIPTION OF THE EMBODIMENTS

In the detailed illustrative embodiments disclosed herein, specific structural and functional details are merely representative for purposes of describing aspects of the present invention. This invention can, however, be embodied in many alternate forms and should not be construed as limited to the embodiments set forth herein.

Accordingly, while the invention and embodiments are susceptible to various modifications and alternative forms, the specific embodiments herein are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of this disclosure and the claims. Like numbers refer to like elements throughout the description of the figures.

It will be understood that, although the terms first, second, etc. can be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Hereinafter, the accompanying drawings and the example embodiments thereof will be explained.

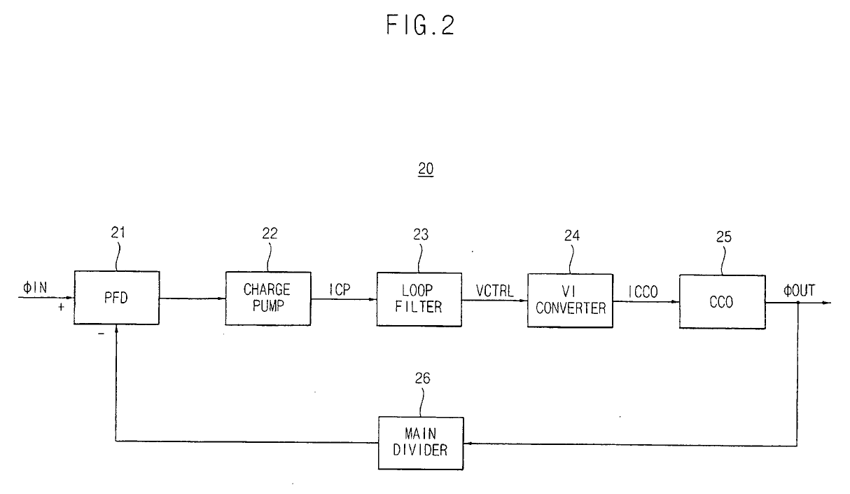

FIG. 2 is a block diagram illustrating an example embodiment of a phase-locked loop (PLL), including a current-controlled oscillator (CCO).

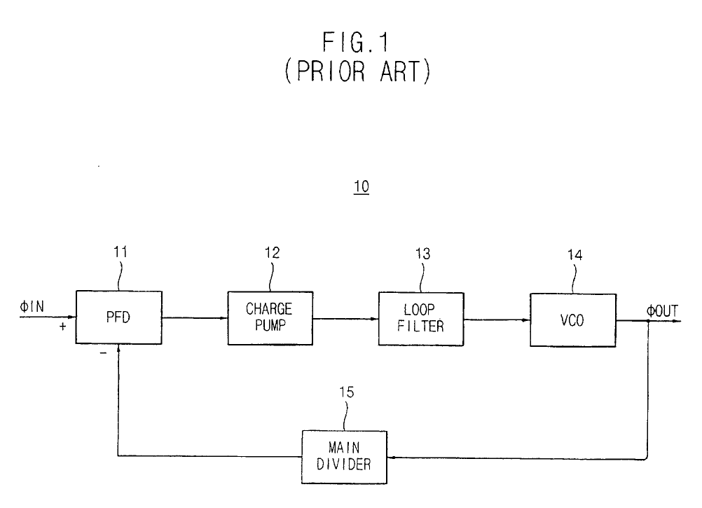

Referring to FIG. 2, a PLL 20 can include a phase-frequency detector (PFD) 21, a charge pump 22, a loop filter 23, a voltage-current (VI) converter 24, a CCO 25 and a main divider 26. The PLL 20 can have a structure similar to the PLL 10 in FIG. 1, but further include the VI converter 24 and the CCO 25 between the loop filter 23 and an output terminal.

The VI converter 24 can convert a voltage provided from the loop filter 23 into a current, and the CCO 25 can generate an output signal φOUT based on the converted current with a proportional constant K_{CCO}. A transfer function of the PLL 20 can be obtained as shown in Expression 3.

$$\begin{matrix}{G}_{2} ( s ) = \frac{{φ}_{out}}{{φ}_{in}} = \frac{\frac{{I}_{CP}}{2 π} \cdot H ( s ) \cdot \frac{{K}_{CCO}}{s}}{1 + \frac{{I}_{CP}}{2 π} \cdot H ( s ) \cdot \frac{{K}_{CCO}}{s}} \\ = \frac{\frac{{I}_{CP} \cdot {K}_{CCO}}{2 π \cdot {C}_{LP} \cdot R} \cdot ( 1 + {sR}_{LP} \cdot {C}_{LP} )}{{s}^{2} + \frac{{I}_{CP} \cdot {K}_{CCO} \cdot {R}_{LP} )}{2 π \cdot M \cdot R} \cdot s + \frac{{I}_{CP} \cdot {K}_{CCO}}{2 π \cdot M \cdot R \cdot {C}_{LP}}}\end{matrix} \\ ( where H ( s ) \approx \frac{1 + {sR}_{LP} \cdot {C}_{LP}}{{sC}_{LP}} ) \qquad [ Expression 3 ]$$

wherein I_{CP} indicates a current provided from the charge pump 22, H(s) indicates an approximate function of a transfer function of the loop filter 23, K_{CCO} indicates a proportional constant of CCO 25, C_{LP} indicates a capacitance of the loop filter 23, and R_{LP} indicates a resistance of the loop filter 23.

A bandwidth of the PLL 20 can be obtained as shown in Expression 4 from a denominator of the transfer function G2(s) in Expression 3.

$$Δ w = \frac{{I}_{CP} \cdot {K}_{CCO} \cdot {R}_{LP}}{2 π \cdot M \cdot R} \qquad [ Expression 4 ]$$

Referring to Expression 4, the bandwidth Δω depends upon the current I_{CP} provided from the charge pump 22, the resistance R_{LP} of the loop filter 23, a conversion constant R of the VI converter 24, the proportional constant K_{CCO} of the CCO 25, and a division ratio M of the main divider 26.

Since the resistance R_{LP} of the loop filter 23 is in a numerator of Expression 4 and the conversion constant R of the VI converter 24 is in a denominator of Expression 4, effects of process, voltage and temperature (PVT) with respect to the resistance R_{LP} and the conversion constant R cancel each other. Thus, the PLL 20 can be less sensitive to PVT variations than a PLL 10 in FIG. 1.

In Expression 4, in case that the resistance R_{LP} of the loop filter 23 and the conversion constant R of the VI converter 24 are substantially the same (e.g., if made through substantially the same process), respective variations can be substantially proportional to each other. The resistance R_{LP} in the numerator and the conversion constant R in the denominator, so that effects of the variations effectively cancel each other. When the PLL has a structure in which effects of the current I_{CP} provided from the charge pump and the proportional constant K_{CCO} of the CCO cancel each other, the bandwidth of the PLL depends upon only a reference signal φREF.

The loop filter 23 can receive the current ICP provided from the charge pump 22 to generate a control voltage VCTRL. The VI converter 24 can receive the control voltage VCTRL to convert the control voltage VCTRL into a control current ICCO (or I_{CCO}). The CCO 25 can receive the control current I_{CCO} to generate the output signal φOUT having a frequency FOUT with the proportional constant K_{CCO}. In case that the control voltage VCTRL is converted into the control current I_{CCO} with a linear proportional relation and the frequency FOUT of the output signal φOUT is generated from the control current I_{CCO} with a linear proportional relation, effects of the current I_{CP} provided from the charge pump 22 and the proportional constant K_{CCO} of the CCO 25 can cancel each other. Thus, the bandwidth of the PLL 20 can depend upon only the reference signal φREF. A PLL having the structure as described above will be described as follows.

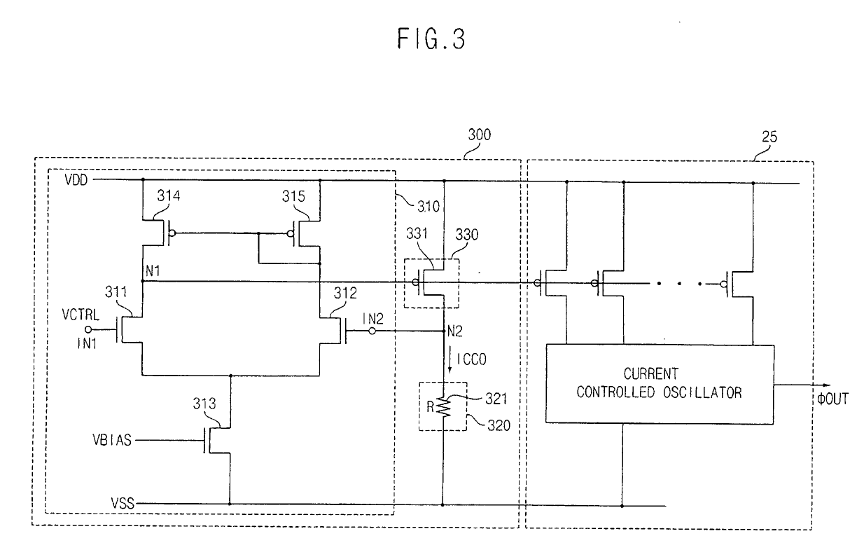

FIG. 3 is a circuit diagram illustrating an example embodiment of a VI converter and a CCO included in a PLL according to aspects of the present invention. Structures of other operational blocks in the PLL are substantially the same as that of a PLL in FIG. 2.

Referring to FIG. 3, a PLL can include a VI converter 300 and a CCO 25. The VI converter 300 can include an amplifying unit 310, a feedback unit 320 and a transconductor 330.

The amplifying unit 310 can include a first N-type metal-oxide semiconductor (NMOS) transistor 311 that is provided with a control voltage VCTRL outputted from a loop filter, a second NMOS transistor 312 that is provided with a fed-back voltage, a third NMOS transistor 313 that provides a constant current IBIAS according to a bias voltage VBIAS to the first and the second NMOS transistors 311 and 312 as a bias current source, and first and second P-type MOS (PMOS) transistors 314 and 315 which operate as an active loads, respectively. The feedback unit 320 can include a feedback resistor 321. The transconductor 330 can include a third PMOS transistor 331.

An output of the amplifying unit 310, namely, a voltage of a first node N1 can be applied to the transconductor 330. A current generated from the transconductor 330 can be provided to the feedback unit 320. A voltage generated from the feedback unit 320 can be applied to a second node N2 as a second input IN2 in the amplifying unit 310.

The operation of the VI converter 300 will be described as follows. In an example embodiment, the control voltage VCTRL provided from the loop filter can be high enough to render the first NMOS transistor 311 to operate in a saturation mode. When the control voltage VCTRL, namely, a first input voltage IN1, is higher than a voltage of the second node N2, namely, a second input voltage IN2, a current flowing through a drain of the first NMOS transistor 311 can be increased. Thus, the voltage of the first node N1 can be decreased, and a gate-source voltage of the third PMOS transistor 331 included in the transconductor 330 can be increased. The transconductor 330 can generate an increased amount of current, and thus a current flowing through the feedback resistor 321 in the feedback unit 320 increases. Eventually, the voltage of the second node N2 can be increased.

When the voltage of the second node N2 increases continuously and becomes higher than the control voltage VCTRL, the current flowing through the drain of the first NMOS transistor 311 can be decreased and the voltage of the first node N1 can be increased. Thus, the gate-source voltage of the third PMOS transistor 331 included in the transconductor 330 can be decreased. The transconductor 330 can generate a decreased amount of current, and thus the current flowing through the feedback unit 320 decreases. Eventually, the voltage of the second node N2 can be decreased.

In this way, the transconductor 330 can control the second input voltage IN2 to be substantially the same as the first input voltage IN1, namely, the control voltage VCTRL. The active loads 314 and 315 can be formed into a current mirror so that the first and the second input voltages IN1 and IN2 can be more stably maintained as having substantially the same value.

As described above, in the VI converter 300, the second input voltage IN2 can be maintained substantially the same as the first input voltage IN1, namely, the control voltage VCTRL, so that the current flowing through the feedback unit 320 can correspond to VCTRL/R and correspond to an output current I_{CCO} flowing to the feedback unit 320. In other words, the VI converter 300 can convert the control voltage VCTRL into the output current I_{CCO} corresponding to VCTRL/R.

The VI converter 300 has both a differential input structure and a feedback structure to be minimally influenced by a power supply variation. In other words, a power-supply rejection ratio (PSRR) in the VI converter 300 is high. Thus, when the control voltage VCTRL is converted into the control current I_{CCO}, the VI converter 300 has a linear proportional relationship with a conversion constant 1/R.

The converted output current I_{CCO} can be provided to the CCO 25 through the current mirror including the first and the second PMOS transistors 314 and 315 as a reference current. The CCO 25 can be implemented as an inverter ring oscillator including N inverters serially coupled with each other, wherein N indicates an odd natural number, and an output of an Nth inverter is fed back into a first inverter, or as a differential inverter ring oscillator including M differential inverters serially coupled with each other, wherein M indicates a natural number, and an output of an Mth inverter is cross-coupled to a first differential inverter so as to be fed back into the first differential inverter.

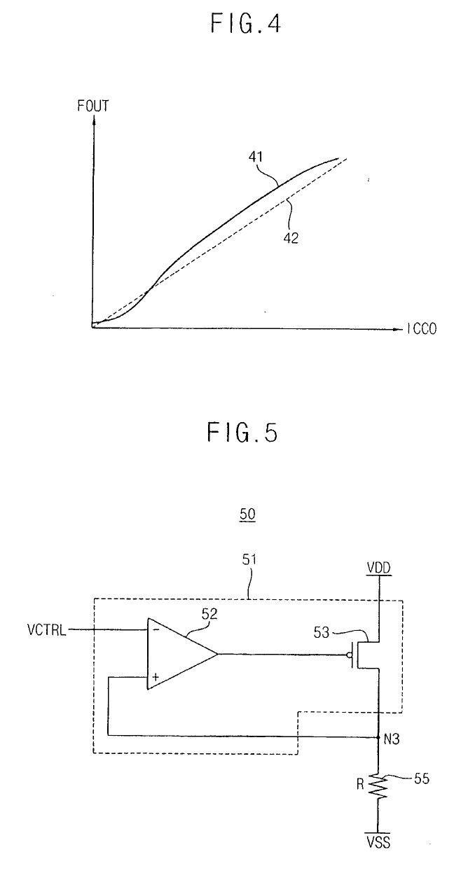

FIG. 4 is a graph illustrating a characteristic curve of a VI conversion in a VI converter included in an example embodiment of a PLL according to aspects of the present invention, and an approximate plot thereof.

Referring to FIG. 4, the x-axis corresponds to a current I_{CCO} provided to the CCO 25 in FIG. 3, and the y-axis corresponds to a frequency FOUT of an output of the CCO 25. The plot can actually form an S-shaped curve 41 that does not cross the origin of the coordinates and has non-ideal characteristics. A slope of the curve 41 corresponds to a ratio of the output signal with respect to the current, and has a value of a proportional constant K_{CCO}. In this case, the proportional constant K_{CCO} of the CCO can be expressed as a straight line 42. Even though the S-shaped curve 41 is approximated to the straight line 42 crossing the origin of the coordinates, a corresponding error can be insignificant.

According to the above description, a transfer function G2(s) of the PLL in FIG. 2 can be re-expressed as described below.

$$Δ w = \frac{{I}_{CP} \cdot {K}_{CCO} \cdot {R}_{LP}}{2 π \cdot M} = \frac{1}{2 π} \cdot \frac{{I}_{CP}}{{I}_{CCO}} \cdot \frac{{R}_{LP}}{R} \cdot {F}_{REF} \qquad [ Expression 5 ]$$

wherein an output current I_{CP} of a charge pump, the output current I_{CCO} of the VI converter, a resistance R_{LP} of a loop filter, and a feedback resistance R of the VI converter can be variable according to PVT variations. However, the output current I_{CP} of the charge pump and the output current I_{CCO} of the VI converter are in a numerator and in a denominator in Expression 5, respectively, and the resistance R_{LP} of the loop filter is in the numerator and the feedback resistance R of the VI converter is in the denominator in Expression 5, so that variations can cancel each other. Thus, the output current I_{CP}, the output current I_{CCO}, the resistance R_{LP} and the feedback resistance R can be considered as one constant term, so that the bandwidth Δω in Expression 5 can depend upon only a reference frequency F_{REF}.

As described above, a PLL including a VI converter and a ring oscillator in FIG. 3 can have a bandwidth that is insensitive to PVT variations.

In Expression 5, contrary to Expression 2, even though the resistance R_{LP} of the loop filter is increased, a frequency band of the PLL can be maintained by raising the resistance R of the VI converter by the same ratio. In other words, the PLL according to example embodiments of the present invention can maintain the frequency band, while raising the resistance of the loop filter and reducing a size of a capacitor of the loop filter. Thus, a size of the PLL can be reduced as a whole.

FIG. 5 is a circuit diagram illustrating another embodiment of a VI converter in FIG. 2.

Referring to FIG. 5, a VI converter 50 can include a unit-gain amplifier 51 and a feedback resistor 55. The unit-gain amplifier 51 can include an operational amplifier 52 and a transconductor 53, to generate a voltage which is substantially the same as a control voltage VCTRL at a third node N3. Thus, a current flowing to the feedback resistor 55 corresponds to VCTRL/R.

As described above, example embodiments of a PLL according to aspects of the present invention can include a VI converter and a CCO to have a frequency bandwidth insensitive to PVT variations. In addition, example embodiments of the PLL according to aspects of the present invention can have a frequency bandwidth insensitive to a division ratio.

Therefore, example embodiments of the PLL according to aspects of the present invention can maintain a frequency bandwidth, a bias feature and the like in spite of a process deviation, a power supply voltage variation, and a temperature variation. Example embodiments of the PLL according to aspects of the present invention can maintain a frequency bandwidth although a division ratio is adjusted so as to control a frequency of an output signal of the PLL. The example embodiments of the PLL according to aspects of the present invention can maintain characteristics of the original circuit and reduce a size of a capacitor of a loop filter, thereby reducing a size of the PLL as a whole.

Having thus described example embodiments, it is to be understood that the invention defined by the appended claims is not to be limited by particular details set forth in the above description, as many apparent variations thereof are possible without departing from the spirit or scope thereof as hereinafter claimed. It is intended by the following claims to claim that which is literally described and all equivalents thereto, including all modifications and variations that fall within the scope of each claim.

What is claimed is:

1. A phase-locked loop (PLL) comprising a phase-frequency detector (PFD), a charge pump, a loop filter, a voltage-current (VI) converter, a current-controlled oscillator (CCO) and a divider, and generating an output signal having a predetermined output frequency, wherein the VI converter comprises:
a first transistor having a gate receiving a control voltage provided from the loop filter;
a second transistor having a gate receiving a drain voltage of the first transistor and a source receiving a power supply voltage;
a feedback resistor configured to convert a drain voltage of the second transistor into a control current according to a conversion constant; and
a third transistor having a gate receiving the drain voltage of the second transistor.

2. A PLL comprising a PFD, a charge pump, a loop filter, a VI converter, a CCO and a divider, and generating an output signal having a predetermined output frequency, wherein the VI converter comprises:
a unit-gain amplifier configured to receive a control voltage provided from the loop filter; and
a feedback resistor configured to receive an output voltage of the unit-gain amplifier to generate a control current.

3. A PLL comprising a PFD, a charge pump, a loop filter, a VI converter, a CCO and a divider, wherein the PLL is configured to generate an output signal having a predetermined output frequency,
wherein a frequency bandwidth of the output signal of the PLL depends upon a current provided from the charge pump, a control current provided from the VI converter, a resistance of the loop filter, a conversion constant of the VI converter and a reference frequency applied to the PFD, and
the VI converter is configured to cancel a variation of the current provided from the charge pump due to effects of process, voltage and temperature (PVT) with a variation of the control current provided from the VI converter due to effects of PVT, and configured to cancel a variation of the resistance of the loop filter due to effects of PVT with a variation of the conversion constant of the VI converter due to effects of PVT.

4. The PLL of claim 3, wherein the VI converter comprises:
a first transistor having a gate configured to receive a control voltage provided from the loop filter;
a second transistor having a gate configured to receive a drain voltage of the first transistor and a source receiving a power supply voltage;
a feedback resistor configured to convert a drain voltage of the second transistor into the control current according to the conversion constant; and
a third transistor having a gate configured to receive the drain voltage of the second transistor.

5. The PLL of claim 3, wherein the VI converter comprises:
a unit-gain amplifier configured to receive a control voltage provided with the loop filter; and
a feedback resistor configured to receive an output voltage of the unit-gain amplifier to generate the control current.

6. The PLL of claim 3, wherein the VI converter is configured to convert a control voltage provided from the loop filter into the control current according to the conversion constant, and the CCO is configured to receive the control current to generate the output signal with a linear approximation.

7. The PLL of claim 3, wherein the CCO comprises an inverter ring oscillator including N inverters serially coupled with each other, wherein N indicates an odd natural number, and an output of an Nth inverter is fed back into a first inverter.

8. The PLL of claim 3, wherein the CCO comprises a differential inverter ring oscillator including M differential inverters serially coupled with each other, wherein M indicates a natural number, and an output of an Mth differential inverter is cross-coupled to a first differential inverter so as to be fed back into the first inverter.
